(19) United States
(12) Patent Application Publication
(10) Pub. No.: US 2013/0288465 A1
(43) Pub. Date: Oct. 31, 2013

(54) METHODS FOR FILLING HIGH ASPECT RATIO FEATURES ON SUBSTRATES

(71) Applicant: APPLIED MATERIALS, INC., Santa Clara, CA (US)

(72) Inventors: IGOR PEIDOUS, Loudonville, NY (US); MICHAEL G. WARD, Niskayuna, NY (US)

(73) Assignee: APPLIED MATERIALS, INC., Santa Clara, CA (US)

(21) Appl. No.: 13/861,856

(22) Filed: Apr. 12, 2013

Related U.S. Application Data
(60) Provisional application No. 61/638,815, filed on Apr. 26, 2012.

(51) Int. Cl. H01L 21/265

(52) U.S. Cl. CPC H01L 21/265
USPC 438/513

(57) ABSTRACT

Methods for filling high aspect ratio features are provided herein. In some embodiments, method of filling a high aspect ratio feature formed in a substrate includes implanting a first species using a first plasma into first surfaces of a first layer formed along the surfaces of the high aspect ratio feature to form implanted first surfaces such that a second species subsequently deposited atop the first layer has an increased mobility along the implanted first surfaces relative to the first surfaces, wherein the first layer substantially prevents the second species from diffusing completely through the first layer; and subsequently filling the high aspect ratio feature with the second species.

### CROSS-REFERENCE TO RELATED APPLICATIONS

This application claims benefit of United States provisional patent application Ser. No. 61/638,815, filed Apr. 26, 2012, which is herein incorporated by reference in its entirety.

### FIELD

Embodiments of the present invention generally relate to substrate processing, and more particularly, to methods of filling high aspect ratio features on substrates.

### BACKGROUND

As the critical dimensions of features continue to shrink, improved processes must be developed to maintain feature quality. For example, processes involving the filling of high aspect ratio features, such as those features having aspect ratios of about 4:1 or greater, can require the deposition of one or several intermediate layers prior to the filling of the feature. High aspect ratio features may be utilized in three-dimensional device architectures, such as FinFETs, thru silicon vias (TSV), dual damascene structures, or the like. Intermediate layers that may be deposited on the surfaces of the high aspect ratio feature prior to filling may include a barrier layer, such as to limit or prevent diffusion of the fill material into the substrate, and/or a wetting layer, such as to reduce the surface energy between the barrier layer and the fill material. Unfortunately, the inventors have discovered that at dimensions of about 10 nanometers (nm), or between about 10 to about 20 nm in width of a opening in a feature, the intermediate layers significantly reduce the size of the opening for filling. Further, due the aspect ratio, the intermediate layers, such as the wetting layer are not deposited uniformly on the surfaces of the feature, which may result in void formation within the feature when filled with the fill material.

Accordingly, improved methods of filling a high aspect ratio feature are provided herein.

### SUMMARY

Methods for filling high aspect ratio features are provided herein. In some embodiments, method of filling a high aspect ratio feature formed in a substrate includes implanting a first species using a first plasma into first surfaces of a first layer formed along the surfaces of the high aspect ratio feature to form implanted first surfaces such that a second species subsequently deposited atop the first layer has an increased mobility along the implanted first surfaces relative to the first surfaces, wherein the first layer substantially prevents the second species from diffusing completely through the first layer; and subsequently filling the high aspect ratio feature with the second species.

In some embodiments, a method of filling a high aspect ratio feature formed in a substrate includes depositing a first layer comprising a first species atop a barrier layer formed along the surfaces of the high aspect ratio feature; implanting an intermetallic reducing species using a first plasma into first surfaces of the first layer to form implanted first surfaces such that the formation of an intermetallic is at least reduced on the implanted first surfaces when the first species is contacted by the second species; and subsequently filling the high aspect ratio feature with the second species.

Other and further embodiments of the present invention are described below.

### BRIEF DESCRIPTION OF THE DRAWINGS

Embodiments of the present invention, briefly summarized above and discussed in greater detail below, can be understood by reference to the illustrative embodiments of the invention depicted in the appended drawings. It is to be noted, however, that the appended drawings illustrate only typical embodiments of this invention and are therefore not to be considered limiting of its scope, for the invention may admit to other equally effective embodiments.

FIG. 1 depicts a flow chart for a method of filling a high aspect ratio feature in accordance with some embodiments of the present invention.

FIGS. 2A-C depict the stages of filling a high aspect ratio feature in accordance with the method depicted in FIG. 1.

FIG. 3 depicts a flow chart for a method of filling a high aspect ratio feature in accordance with some embodiments of the present invention.

FIGS. 4A-C depict the stages of filling a high aspect ratio feature in accordance with the method depicted in FIG. 3.

FIG. 5 depicts a schematic side view of a toroidal source plasma immersion ion implantation reactor suitable for performing at least portions of the methods described herein.

To facilitate understanding, identical reference numerals have been used, where possible, to designate identical elements that are common to the figures. The figures are not drawn to scale and may be simplified for clarity. It is contemplated that elements and features of one embodiment may be beneficially incorporated in other embodiments without further recitation.

### DETAILED DESCRIPTION

The present invention provides methods for filling high aspect ratio features. Embodiments of the inventive methods may advantageously provide thinner, more uniform intermediate layers, such as barrier and/or wetting layers, such that the opening of a high aspect ratio feature is not substantially constricted for filling with a fill material. Further, in some embodiments, the inventive methods may advantageously reduce or prevent the formation of an intermetallic when filling high aspect ratio features.

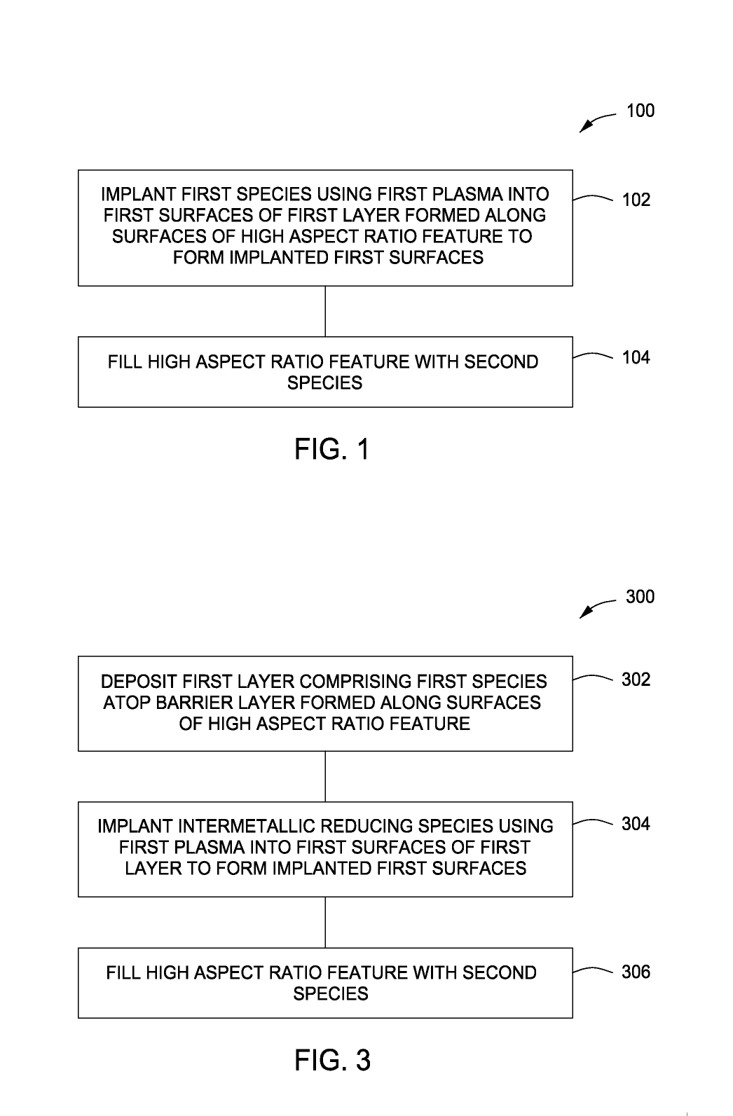

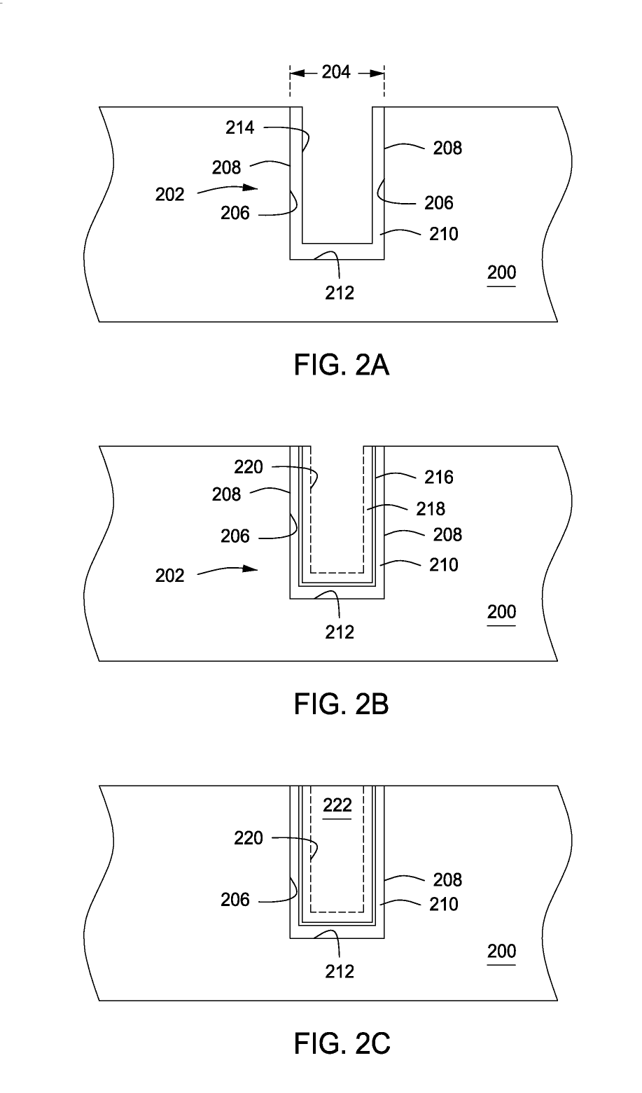

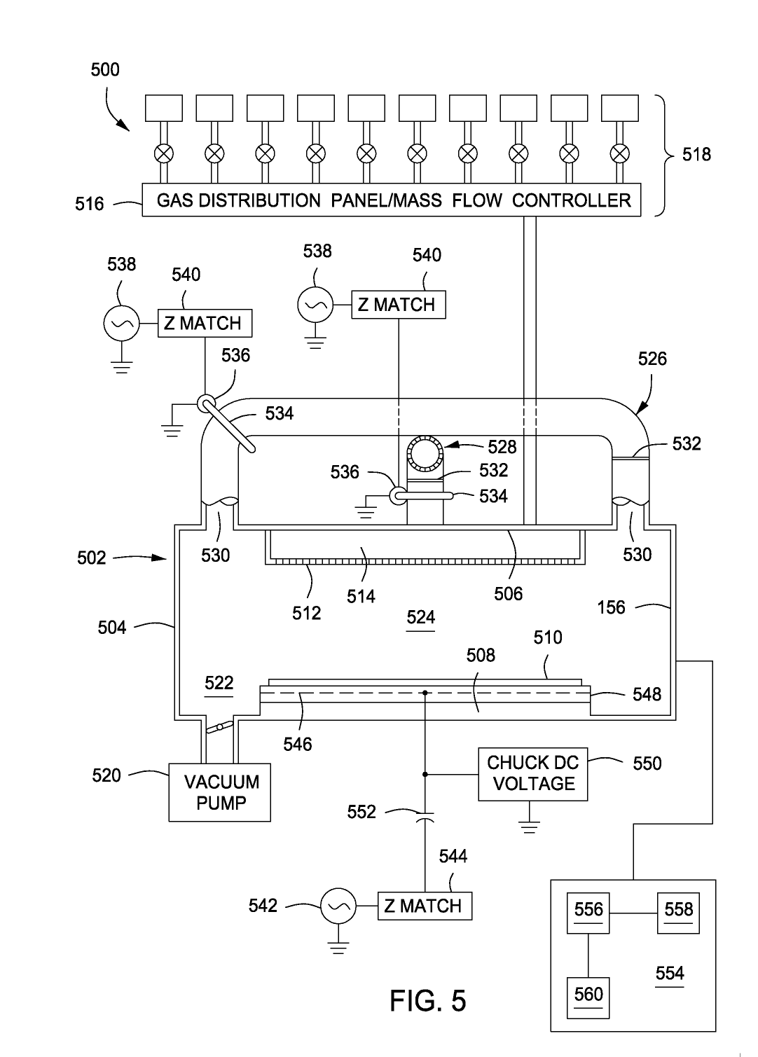

FIG. 1 depicts a flow chart for a method 100 of filling a high aspect ratio feature in accordance with some embodiments of the present invention. The method 100 may be described below in accordance with stages of filling a high aspect ratio feature as illustrated in FIG. 2A-C. The inventive methods described herein may be performed using a toroidal source plasma immersion ion implantation reactor 500, which is discussed below and illustrated in FIG. 5.

FIG. 2A depicts a substrate 200 having a high aspect ratio feature 202 disposed therein. The high aspect ratio feature 202 may have an aspect ratio of about 4:1 or higher, or ranging from about 4:1 to about 50:1. As used herein the aspect ratio is defined as the ratio of the height to the width of the feature. In some embodiments, the width of an opening 204 as defined between opposing surfaces 206 of the sidewalls 208 of the feature 202 may range from about 10 to about 20 nm. In some embodiments, the opening 204 may have a width of about 10 nm.

The substrate 200 may be any suitable substrate, such having 200 mm, 300 mm, or 450 mm diameters. The substrate 200 may comprise any suitable materials, such as silicon, dielectric materials, or the like. In some embodiments, the substrate 200 may include a dielectric material, such as low-k dielectric material, for example, having a dielectric constant of about 3.9 or lower. Examples of low-k dielectric material include, but are not limited to, fluorine-doped silicon dioxide, carbon-doped silicon dioxide, porous silicon dioxide, porous carbon-doped silicon dioxide, spin-on organic polymeric dielectric materials, or spin-on silicone based polymeric dielectric materials. The low-k dielectric material can be porous, and thus may be susceptible to penetration by any material used to fill the feature 202.

In some embodiments, a first layer 210 (e.g., a barrier layer) may be disposed on the surfaces 206 of the sidewalls 208 and on a bottom surface 212 of the feature 202 to limit or prevent penetration of a fill material (e.g., a second species as discussed below at 104) into the substrate 200. The first layer 210 may comprise suitable materials to provide the barrier function discussed above. In some embodiments, the first layer 210 may comprise one or more of titanium nitride (TiN), tantalum nitride (TaN), titanium (Ti), a titanium/tantalum alloy or mixture (TiTa), or the like. In some embodiments, the first layer 210 may have a thickness ranging from about 0.5 to about 5 nm. The first layer 210 may be formed by any suitable methods, such as chemical vapor deposition (CVD), physical vapor deposition (PVD), or the like.

The first layer 210 may have first surfaces 214 having a high surface energy with respect to the fill material. For example, high surface energy of the first surfaces 214 of the first layer 210 may cause the fill material to cluster, or agglomerate, on the first surfaces, or to otherwise deposit unevenly, which may cause void formation in the final filled feature 202. Accordingly, in some embodiments, a wetting layer can be utilized to lower the surface energy on the first surfaces 214. However, the inventors have found conventional methods for depositing wetting layers, such as chemical vapor deposition (CVD), physical vapor deposition (PVD), atomic layer deposition (ALD), etc., to be inadequate for depositing a wetting layer that is sufficiently thin, for example, between about 0.5 to about 2 nm as well as uniformly deposited on the first surfaces 214 of the first layer 210. Further, although the inventors have found PVD to be inadequate for high aspect ratio features on substrates of 200 or 300 mm diameters, they have further discovered that PVD may provide limited if any deposition of the wetting layer on the sidewalls of features proximate the peripheral edges of larger substrates, such as those having 450 mm diameters.

The method 100 generally beings at 102 by implanting a first species using a first plasma into the first surfaces 214 of the first layer 210 to form implanted first surfaces 216 as illustrated in FIG. 2B. The first species may be selected at least in part such that a second species, e.g., the fill material, discussed at 104 below, will have increased mobility along the implanted first surfaces 216 relative to the first surfaces 214. The increased mobility of the second species facilitates more uniform deposition, which in turn may limit or prevent the formation of voids in the final filled feature. For example, the increased mobility may result in a more uniform deposition of the second species on the implanted first surfaces 216. The first species may be any suitable species that may be used to reduce surface energy between a surface and the second species. Exemplary first species may include one or more of copper (Cu), aluminum (Al), titanium (Ti), nickel (Ni), vanadium (V), cobalt (Co), zirconium (Zr), silicon (Si), niobium (Nb), alloys thereof, or the like.

The first species may be implanted using the toroidal source plasma immersion ion implantation reactor 500, discussed below. For example, by adjusting one or more of the RF bias on the substrate 200 (e.g., using RF bias power generator 542), the concentration of a first species precursor gas used to form the first plasma, the gas pressure, the precursor gas dilution with inert gases, or the like, the concentration and/or the depth of the implanted first surfaces 216 can be controlled. For example, the concentration of first species in the implanted first surfaces 216 may range from about 1 to about 100 atomic percent. Exemplary depths for the implanted first surface 216 may range from about 0.5 to about 1 nm.

Optionally, in some embodiments, a second layer 218 comprising the first species may be deposited atop the implanted first surfaces 216 of the first layer 210 using the first plasma (or another plasma—for example, using different precursors, different concentrations of precursors, or different process conditions than in the first plasma). The second species may have a higher mobility along second surfaces 220 of the second layer 218 than along the implanted first surfaces 216. For example, a second layer 218 may be optionally utilized when the improved surface mobility created by the implanted first surfaces 216 remains insufficient to limit or prevent void formation in the final filled feature. Utilization of the second layer 218 may be dependent on the identity of the first layer 210, and/or the identity of the first and/or second species. In some embodiments, the second layer 218 may have a thickness ranging from about 0.5 to about 10 nm.

The second layer 218 can be deposited using the reactor 500, for example, in a deposition rather than an implant mode, where the implant mode is used to form the implanted first surfaces 216. For example, in some embodiments, the implantation and deposition modes can be at least partially controlled by the amount of RF energy provided to the first plasma to accelerate ions in the first plasma towards the feature 202. In implant mode, such as when forming the implanted first surfaces 216, a first RF energy may be applied to the substrate 200 to provide a first ion energy to the first species to implant the first species into the first surfaces 214 of the first layer 210. In deposition mode, such as when forming the second layer 218, a second RF energy may be applied to the substrate 200 to provide a second ion energy to the first species to deposit the second layer 210, where the second ion energy is less than the first ion energy.

At 104, subsequent to either forming the implanted first surfaces 216 or depositing the optional second layer 218, the high aspect ratio feature 202 may be filled with the second species, e.g., the fill material 222 which is illustrated in FIG. 2C. The second species may be a single species, such as one metal, or alternatively, multiple species, such two or more metals that can form an alloy. The second species may be deposited by any suitable methods, including those methods using the reactor 500. For example, in some embodiments, the first and second species may be the same species. As such, instead of depositing a second layer 210 as discussed above, the deposition mode of the reactor 500 may be utilized to fill the feature 202 entirely. Alternatively, when the second species is different from the first species, the deposition mode may be utilized to fill the feature 202 with the second species in substantially similar manner utilized to deposit the second layer 210.

Alternative methods of filling the feature 202 with the second species are possible. For example, a plasma deposition method can be used to deposit the second species using a second plasma. For example, such a deposition method may include any suitable deposition process that may utilize a plasma, such as CVD, PVD, or the like. Alternatively, the second species may be deposited using an electroplating process to electroplate the second species onto either the implanted first surfaces 216 or the second layer 210 to fill the feature 202. Alternatively, the high aspect ratio feature 202 may be filled using an ALD process. For example, an ALD process may include depositing a first precursor onto the implanted first surface 216 or second layer 218 and depositing a second precursor onto the implanted first surface 216 or second layer 218, wherein at least one of the first or second precursors includes the second species. For example, the first and second precursors could be the same. Alternatively, the first and second precursors may be different where one or both include the second species. The first and second precursors can be reacted to form a first atomic layer of the second species on the implanted first surfaces 216 or the second layer 218. The preceding ALD process can be repeated to fill the feature 202.

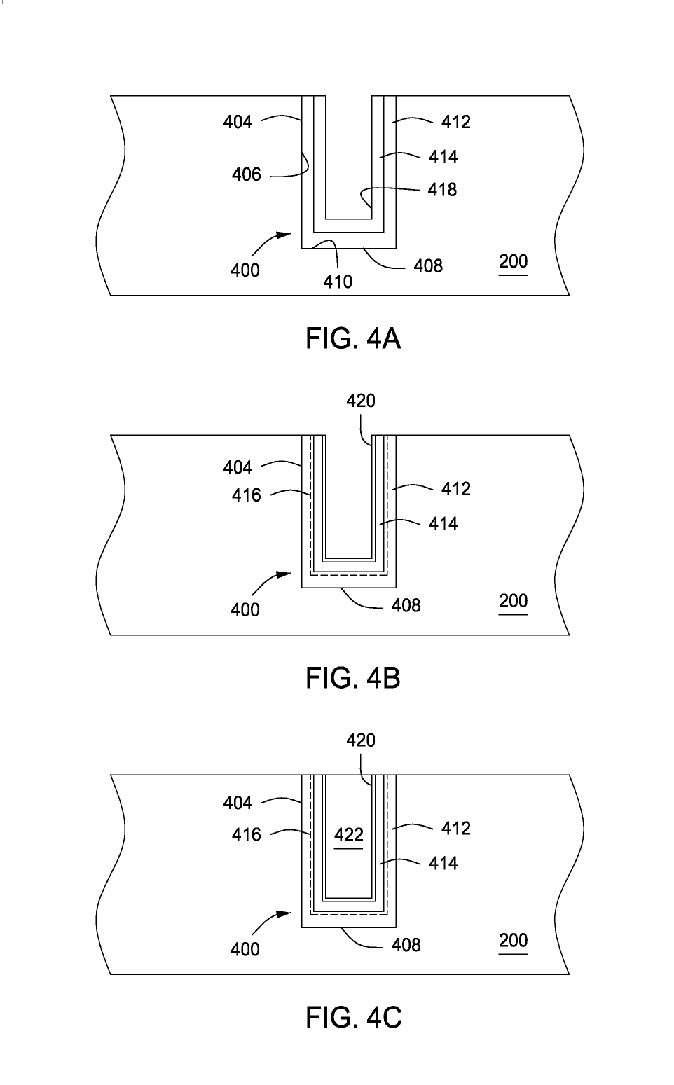

FIG. 3 depicts a flow chart for a method 300 for filling a high aspect ratio feature in accordance with some embodiments of the present invention. For example, the method 300 may be used in combination with the method 100, such as after the second layer 210 has been deposited, or alternatively may be used separate from the method 100. Further, the method 300 may be applied to high aspect ratio features, such as those described above, or alternatively, may be utilized with features having aspect ratios other than high aspect ratios, and/or with features having larger critical dimensions, for example, such as having a width of an opening in the feature ranging from about 100 to about 10,000 nm. The method 300 is described below in accordance to the stages of filling a high aspect ratio feature 400 as illustrated in FIG. 4A-C. The feature 400 may be substantially similar to the feature 202 or may have an aspect ratio other than a high aspect ratio and/or a larger critical dimension than the feature 202.

As illustrated in FIG. 4A, the feature 400 may be disposed in the substrate 200 and may include sidewalls 404 having surfaces 406 and a bottom wall 408 having a bottom surface 410. A barrier layer 412 may be deposited on the surfaces 406 and the bottom surface 410 by any suitable method. The barrier layer 412 may be substantially similar to the first layer 210 as discussed above.

The method 300 generally begins at 302 by depositing a first layer 414 comprising the first species atop the barrier layer 412. The first layer 414 may be substantially similar to the second layer 210; however, unlike the second layer 210, the first layer 414 may be deposited by any suitable methods including the deposition mode used to deposit the second layer 210 as discussed above. For example, the first layer 414 may be deposited using a plasma. Alternatively, the first layer 414 may be deposited by sputtering the first species from a target, such as a target in a PVD apparatus disposed above the substrate 200. Alternatively, the first layer 414 may be deposited by reacting a first process gas and a second process gas above the feature 400 to form a vapor including the first species, and exposing the feature 400 to the vapor to deposit the first layer 414.

Optionally, the implant mode as discussed above may be utilized to form implanted surfaces 416 of the barrier layer 412 prior to depositing the first layer 414 using the deposition mode or an alternative method as discussed above. The implanted surfaces 416 may be substantially similar to the implanted first surfaces 216 as discussed above.

At 304, using the implant mode of the reactor 500, an intermetallic reducing species may be implanted into first surfaces 418 of the first layer 414 to form implanted first surfaces 420, as shown in FIG. 4B, such that the formation of an intermetallic is at least reduced on the implanted first surfaces 420 when the first species of the first layer 414 is contacted by the second species, e.g., a fill material used to fill the feature 400 at 406 as discussed below. The second species may have increased mobility along the first surfaces 418 or the implanted first surfaces 420 relative to surfaces of the barrier layer 412. Exemplary intermetallic reducing species may include silicon (Si), carbon (C), nitrogen (N), oxygen (0), or the like.

Absent the intermetallic reducing species, an intermetallic may form when the second species is deposited to fill the feature 400. Exemplary intermetallics may include aluminum and cobalt alloys or mixtures, gold and aluminum alloys or mixtures, copper and tin alloys or mixtures, or the like. The formation of intermetallics may disadvantageously increase the resistance of the final filled feature 400 and/or change the material volume, which may result in void formation in the final filled feature 400.

At 306, subsequent to implanting the intermetallic reducing species at 404, the feature 400 is filled with the second species, e.g., the fill material 422, as illustrated in FIG. 4C. The fill at 306 may be substantially similar to that described with respect to 104 of method 100, discussed above.

Referring to FIG. 5, a toroidal source plasma immersion ion implantation (“P3i”) reactor 500 is described that is suitable for performing the implantation and some of the deposition processes described above. The reactor 500 may include a cylindrical vacuum chamber 502 defined by a cylindrical side wall 504 and a disk-shaped ceiling 506. A substrate support 508 at the floor of the chamber supports the substrate 200 to be processed. A gas distribution plate or showerhead 512 on the ceiling 506 receives process gas in its gas manifold 514 from a gas distribution panel 516 whose gas output can be any one of or mixtures of gases from one or more individual gas supplies 518. A vacuum pump 520 is coupled to a pumping annulus 522 defined between the substrate support 508 and the sidewall 504. A processing region 524 is defined between the substrate 200 and the gas distribution plate 512.

A pair of external reentrant conduits 526, 528 establishes reentrant toroidal paths for plasma currents passing through the processing region 524, and the toroidal paths intersecting in the processing region 524. Each of the conduits 526, 528 has a pair of ends 530 coupled to opposite sides of the chamber. Each conduit 526, 528 is a hollow conductive tube. Each conduit 526, 528 has a D.C. insulation ring 532 preventing the formation of a closed loop conductive path between the two ends of the conduit.

An annular portion of each conduit 526, 528, is surrounded by an annular magnetic core 534. An excitation coil 536 surrounding the core 534 is coupled to an RF power source 538 through an impedance match device 540. The two RF power sources 538 coupled to respective ones of the cores 536 may be of two slightly different frequencies. The RF power coupled from the RF power generators 538 produces plasma ion currents in closed toroidal paths extending through the respective conduit 526, 528 and through the processing region 524. These ion currents oscillate at the frequency of the respective RF power source 538. Bias power is applied to the substrate support 508 by a bias power generator 542 through an impedance match circuit 544 and/or or a DC power source 550.

Plasma formation is performed by introducing a process gas, or mixture of process gases into the chamber 524 through the gas distribution plate 512 and applying sufficient source power from the generators 538 to the reentrant conduits 526, 528 to create toroidal plasma currents in the conduits and in the processing region 524.

The plasma flux proximate the substrate surface is determined by the substrate bias voltage applied by the RF bias power generator 542. The plasma rate or flux (number of ions sampling the substrate surface per square cm per second) is determined by the plasma density, which is controlled by the level of RF power applied by the RF source power generators 538. The cumulative ion dose (ions/square cm) at the substrate 200 is determined by both the flux and the total time over which the flux is maintained.

If the substrate support 508 is an electrostatic chuck, then a buried electrode 546 is provided within an insulating plate 548 of the substrate support, and the buried electrode 546 is coupled to the bias power generator 542 through the impedance match circuit 544 and through an optional isolation capacitor 552 (which may be included in the impedance match circuit 544) and/or to the DC power source 550.

In operation, and for example, the substrate 200 may be placed on the substrate support 508 and one or more process gases may be introduced into the chamber 502 to strike a plasma from the process gases.

In operation, a plasma may be generated from the process gases within the reactor 500 to selectively modify surfaces of the substrate 200 as discussed above. The plasma is formed in the processing region 524 by applying sufficient source power from the generators 538 to the reentrant conduits 526, 528 to create plasma ion currents in the conduits 526, 528 and in the processing region 524 in accordance with the process described above. In some embodiments, the substrate bias voltage delivered by the RF bias power generator 542 can be adjusted to control the flux of ions to the substrate surface, and possibly one or more of the thickness a layer formed on the substrate or the concentration of plasma species embedded in the substrate surface.

A controller 554 comprises a central processing unit (CPU) 556, a memory 558, and support circuits 560 for the CPU 556 and facilitates control of the components of the chamber 502 and, as such, of the etch process, as discussed below in further detail. To facilitate control of the chamber 502, for example as described below, the controller 554 may be one of any form of general-purpose computer processor that can be used in an industrial setting for controlling various chambers and sub-processors. The memory 558, or computer-readable medium, of the CPU 556 may be one or more of readily available memory such as random access memory (RAM), read only memory (ROM), floppy disk, hard disk, or any other form of digital storage, local or remote. The support circuits 560 are coupled to the CPU 556 for supporting the processor in a conventional manner. These circuits include cache, power supplies, clock circuits, input/output circuitry and subsystems, and the like. The inventive methods, or at least portions thereof, described herein may be stored in the memory 558 as a software routine. The software routine may also be stored and/or executed by a second CPU (not shown) that is remotely located from the hardware being controlled by the CPU 556.

While the foregoing is directed to embodiments of the present invention, other and further embodiments of the invention may be devised without departing from the basic scope thereof.

1. A method of filling a high aspect ratio feature formed in a substrate, comprising:
implanting a first species using a first plasma into first surfaces of a first layer formed along the surfaces of the high aspect ratio feature to form implanted first surfaces such that a second species subsequently deposited atop the first layer has an increased mobility along the implanted first surfaces relative to the first surfaces, wherein the first layer substantially prevents the second species from diffusing completely through the first layer; and
subsequently filling the high aspect ratio feature with the second species.

2. The method of claim 1, further comprising:
depositing a second layer comprising the first species atop the implanted first surfaces of the first layer using the plasma prior to filling the high aspect ratio feature with the second species, wherein the second species has a higher mobility along second surfaces of the second layer than along the implanted first surfaces.

3. The method of claim 2, further comprising:
applying a first RF energy to the substrate to provide a first ion energy to the first species to implant the first species into the first surfaces of the first layer; and
applying a second RF energy to the substrate to provide a second ion energy to the first species to deposit the second layer, wherein the second ion energy is less than the first ion energy.

4. The method of claim 1, wherein the first and second species are the same species, and further comprising:
applying a first RF energy to the substrate to provide a first ion energy to the species to implant the species into the first surfaces of the first layer; and
applying a second RF energy to the substrate to provide a second ion energy to the species to fill the high aspect ratio feature, wherein the second ion energy is less that the first ion energy.

5. The method of claim 1, where the substrate comprises a dielectric material.

6. The method of claim 1, wherein the high aspect ratio feature has an aspect ratio, defined by a ratio of the length to the width of the feature greater than about 4:1.

7. The method of claim 6, wherein the width of the high aspect ratio feature ranges from about 10 to about 20 nm.

8. The method of claim 1, wherein the first layer comprises one or more of titanium nitride (TiN), tantalum nitride (TaN), titanium (Ti), tantalum (Ta), or titanium tantalum nitride (TiTaN).

9. The method of claim 1, wherein the first species comprises one or more of copper (Cu), aluminum (Al), titanium (Ti), nickel (Ni), vanadium (V), cobalt (Co), zirconium (Zr), silicon (Si), or niobium (Nb).

10. The method of claim 1, wherein filling the high aspect ratio feature with the second species further comprises:
depositing the second species using a second plasma.

11. The method of claim 1, wherein filling the high aspect ratio feature with the second species further comprises:
depositing the second species by electroplating the second species onto the implanted first surfaces.

12. The method of claim 1, wherein filling the high aspect ratio feature with the second species further comprises:
(a) depositing a first precursor onto the implanted first surface;
(b) depositing a second precursor onto the implanted first surface, wherein at least one of the first or second precursors include the second species;
(c) reacting the first and second precursors to form a first atomic layer of the second species on the implanted first surfaces; and
(d) repeating (a)—(c) to fill the high aspect ratio feature with the second species.

13. The method of claim 1, wherein filling the high aspect ratio feature with the second species further comprises:
reacting a first process gas and a second process gas above the high aspect ratio feature to form a vapor including the second species; and
exposing the high aspect ratio feature to the vapor to fill the high aspect ratio feature with the second species.

14. A method of filling a high aspect ratio feature formed in a substrate, comprising:
depositing a first layer comprising a first species atop a barrier layer formed along the surfaces of the high aspect ratio feature;
implanting an intermetallic reducing species using a first plasma into first surfaces of the first layer to form implanted first surfaces such that the formation of an intermetallic is at least reduced on the implanted first surfaces when the first species is contacted by the second species; and
subsequently filling the high aspect ratio feature with the second species.

15. The method of claim 14, wherein the second species have increased mobility along the first surfaces or implanted first surfaces of the first layer relative to second surfaces of the barrier layer.

16. The method of claim 15, wherein depositing the first layer further comprises:
depositing the first layer using a second plasma.

17. The method of claim 16, further comprising:
implanting the first species using the second plasma into the second surfaces of the barrier layer prior to depositing the first layer.

18. The method of claim 17, further comprising:
applying a first RF energy to the substrate to provide a first ion energy to the first species to implant the first species into the barrier layer; and
applying a second RF energy to the substrate to provide a second ion energy to the first species to deposit the first layer, wherein the second ion energy is less that the first ion energy.

19. The method of claim 15, wherein depositing the first layer further comprises:
sputtering the first species from a target disposed above the substrate to deposit the first layer.

20. The method of claim 15, wherein depositing the first layer further comprises:
reacting a first process gas and a second process gas above the high aspect ratio feature to form a vapor including the first species; and
exposing the high aspect ratio feature to the vapor to deposit the first layer.
